(19) United States
(12) Patent Application Publication
(10) Pub. No.: US 2025/0192540 A1
(43) Pub. Date: Jun. 12, 2025

(54) PROTECTION CIRCUIT AND SEMICONDUCTOR DEVICE INCLUDING THE PROTECTION CIRCUIT

(71) Applicant: ABLIC Inc., Nagano (JP)

(72) Inventor: Tsutomu TOMIOKA, Nagano (JP)

(73) Assignee: ABLIC Inc., Nagano (JP)

(21) Appl. No.: 18/970,845

(22) Filed: Dec. 5, 2024

(30) Foreign Application Priority Data
Dec. 12, 2023 (JP) 2023-208938
Oct. 22, 2024 (JP) 2024-185783

(51) Int. Cl. H02H 3/18; H10D 89/60

(52) U.S. Cl. CPC H02H 3/18; H10D 89/811

(57) ABSTRACT

The protection circuit is formed on a semiconductor substrate having a triple well structure including substrate, partition, and well regions, and is a protection circuit protecting a protected circuit from application of a power voltage with reverse polarity relative to a steady state. The protected circuit includes a noise source and is connected to a GND terminal via the protection circuit between VDD and GND terminals. The protection circuit includes a first protection transistor including a source and a back gate connected to a node with a first circuit and a second protection transistor including a source and a back gate connected to a node connected to a second circuit while being unconnected to the first circuit. The partition region in the substrate region or the substrate region is connected to a drain of a protection transistor in a well region in the partition region.

### CROSS-REFERENCE TO RELATED APPLICATION

This application claims the priority benefit of Japan application serial no. 2023-208938 filed on Dec. 12, 2023 and Japan application serial no. 2024-185783 filed on Oct. 22, 2024. The entirety of each of the above-mentioned patent applications is hereby incorporated by reference herein and made a part of this specification.

### BACKGROUND

### Technical Field

The present invention relates to a protection circuit and a semiconductor device including the protection circuit.

### Description of Related Art

A power supply device (e.g., a secondary battery, etc.) that supplies power to a semiconductor device may apply a power voltage with polarity (hereinafter simply referred to as “reverse polarity”) opposite to the polarity applied in a steady state due to reverse connection of connectors or noise, etc. Generally, a semiconductor device is configured to include a parasitic diode forward biased with respect to a power voltage of reverse polarity. Thus, when the power voltage of reverse polarity is applied to a semiconductor device not designed to be applied with such a voltage, an excessive forward current may flow through the parasitic diode, potentially damaging the elements forming the semiconductor device. From the perspective of preventing damage to elements caused by the application of such power voltage with reverse polarity, techniques for protecting an integrated circuit have been disclosed (e.g., see Patent Document 1).

The protection circuit applying the technique disclosed in Patent Document 1 includes an NPN bipolar transistor, and the NPN bipolar transistor includes: a base connected to a VCC terminal that supplies a power voltage VCC (≠0V) through a resistor, a collector connected to a protected internal circuit (hereinafter referred to as “protection object” or “protected circuit”), and an emitter connected to a GND terminal that supplies a power voltage of 0V.

In a state where the power voltage of reverse polarity is not applied, that is, in the steady state where the power voltage VCC is a positive voltage (VCC>0), if the power voltage VCC is sufficiently higher than a forward voltage Vf of a base-emitter diode of the NPN bipolar transistor, the current driving capability increases and a collector-emitter voltage can be considered as approximately 0V. Thus, in the steady state, the internal circuit can be considered as directly connected to the GND terminal.

On the other hand, in the state where the power voltage of reverse polarity is applied, that is, in a power supply reverse connection state where the power voltage VCC is a negative voltage (VCC<0), the base voltage follows the power voltage VCC and the base current stops flowing. As a result, the NPN bipolar transistor provided in the protection circuit enters a cut-off state, and the collector current is blocked. By blocking the collector current, it is possible to block an excessive forward current passing through the parasitic diode that may cause damage to an element when the internal circuit is directly connected to the GND terminal. Consequently, the protection object can be protected from damage to an element caused by the application of the power voltage of reverse polarity.

However, in the conventional protection circuit applying the technology disclosed in Japanese Patent Application Laid-open No. H10-289956 and the semiconductor device including such protection circuit, there is room for improvement in that there may be an adverse effect on the protection object by using the circuit configuration as the protection object. For example, in the case where the circuit as the protection object is a circuit mixing an analog circuit handling a DC voltage or a continuous signal in an internal circuit, and a switching power supply or a charge pump with a large current flow accompanying a switching operation, or a digital circuit handling a discrete signal, fluctuations in a collector voltage are generated in accordance with a current flowing from a digital circuit or a DC-DC converter to the NPN bipolar transistor in the steady state The fluctuations of the collector voltage become the noise of the analog circuit, which adversely affects the signal processing of the analog circuit.

To reduce the noise of the analog circuit, it is possible to replace the NPN bipolar transistor in the protection circuit with an NPN bipolar transistor having higher current driving capability. However, the area of the bipolar transistor tends to increase as the current driving capability increases. Thus, the application of an NPN bipolar transistor with high current driving capability leads to an increase in the area of the protection circuit, and consequently, an increase in cost.

Considering the circumstances, an objective of the present invention is to provide a protection circuit capable of protecting the protection object from the application of a power voltage of reverse polarity while suppressing the increase in cost and the undesirable effects on the protection object, and a semiconductor device including the protection circuit.

### SUMMARY

A protection circuit according to an embodiment of the present invention is formed on a semiconductor substrate and protects a protected circuit from application of a power voltage with reverse polarity relative to a steady state. The semiconductor substrate has, in at least a portion, a triple well structure including: a substrate region having a first conductivity type; a partition region formed in the substrate region, the partition region including, in at least a portion, a semiconductor region having a second conductivity type; and a well region having the first conductivity type and formed in an inner part surrounded by the partition region. The protected circuit includes: a noise source; a first circuit, arranged between a first power terminal and a second power terminal and connected to the second power terminal via the protection circuit; and a second circuit connected in parallel with the first circuit via the protection circuit between the first power terminal and the second power terminal. The protection circuit includes: a first protection transistor including: a drain, connected to the second power terminal; a gate receiving supply of a first control voltage; and a source and a back gate which are connected to the first circuit; and a second protection transistor, comprising: a drain, connected to the drain of the first protection transistor; a gate receiving supply of a second control voltage; and a source and a back gate which are connected to the second circuit while not connected to a connection point between the source and the back gate of the first protection transistor and the first circuit. At least one protection transistor of the first protection transistor and the second protection transistor is formed in the well region. A drain of the at least one protection transistor is connected to one of the substrate region and the semiconductor region comprised in the partition region surrounding the well region. A semiconductor device according to an embodiment of the present invention includes the protection circuit.

### BRIEF DESCRIPTION OF THE DRAWINGS

FIG. 1 is a circuit diagram of a semiconductor device including a protection circuit according to an embodiment of the present invention.

FIG. 2A is a circuit diagram illustrating a current source as a first configuration example of a load in a voltage drop circuit of the semiconductor device according to the embodiment, FIG. 2B is a circuit diagram illustrating a first configuration example of the current source as the load, and FIG. 2C is a circuit diagram illustrating a second configuration example of the current source as the load.

FIG. 3 is a cross-sectional view of the protection circuit included in the semiconductor device according to the first embodiment.

FIG. 4 is a cross-sectional view of a protection circuit included in a semiconductor device according to a second embodiment.

FIG. 5 is a cross-sectional view illustrating a first modified example of the semiconductor device according to the first embodiment.

FIG. 6 is a cross-sectional view illustrating a second modified example of the semiconductor device according to the first embodiment.

FIG. 7 is a cross-sectional view illustrating a third modified example of the semiconductor device according to the first embodiment.

FIG. 8A is a circuit diagram illustrating a second configuration example of the load in the semiconductor device according to the embodiment, FIG. 8B is a circuit diagram illustrating a third configuration example of the load in the semiconductor device according to the embodiment, and FIG. 8C is a circuit diagram illustrating a fourth configuration example of the load in the semiconductor device according to the embodiment.

FIG. 9A is a circuit diagram illustrating a second configuration example of the voltage drop circuit in the semiconductor device according to the embodiment, and FIG. 9B is a partial circuit diagram of a third configuration example of the voltage drop circuit.

FIG. 10A is a circuit diagram illustrating a first configuration example of a current source in the second configuration example of the voltage drop circuit in the semiconductor device according to the embodiment, and FIG. 10B is a circuit diagram illustrating a second configuration example of the same current source.

FIG. 11 is a circuit diagram illustrating a modification example of the protection circuit and the semiconductor device according to the embodiment.

### DESCRIPTION OF THE EMBODIMENTS

According to the present invention, it is possible to protect the protection object from the application of the power voltage of reverse polarity while suppressing the increase in cost and the adverse effects on the protection object.

With reference to the accompanying drawings, the following describes a protection circuit according to the embodiments of the present invention and a semiconductor device including the protection circuit by using a circuit in which a circuit including a noise source and a circuit that may be affected by the noise as the protection object, i.e., the protected circuit, protected by the protection circuit according to the embodiments of the present invention.

### First Embodiment

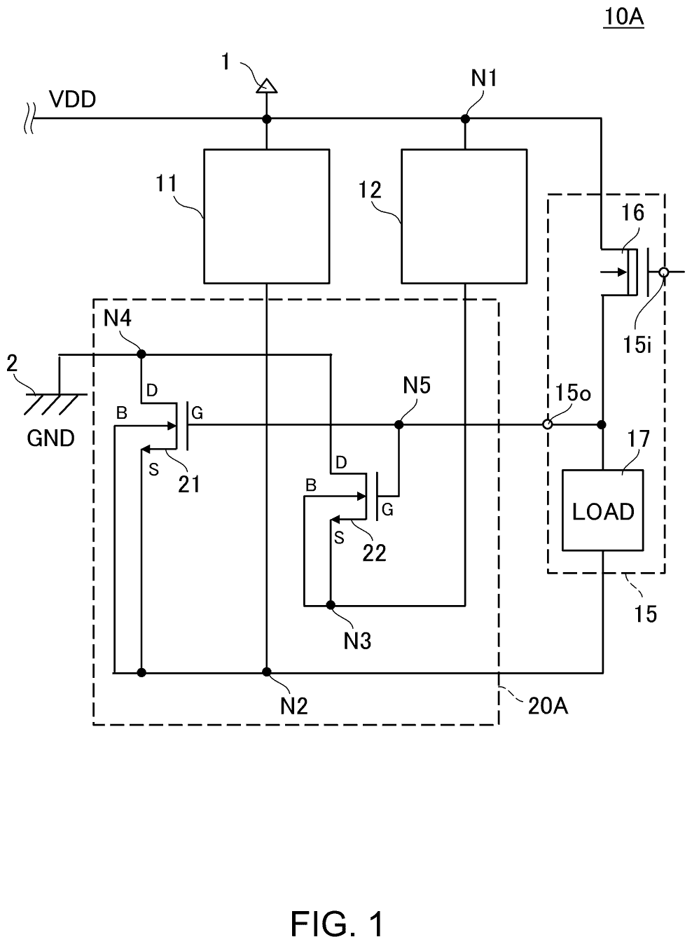

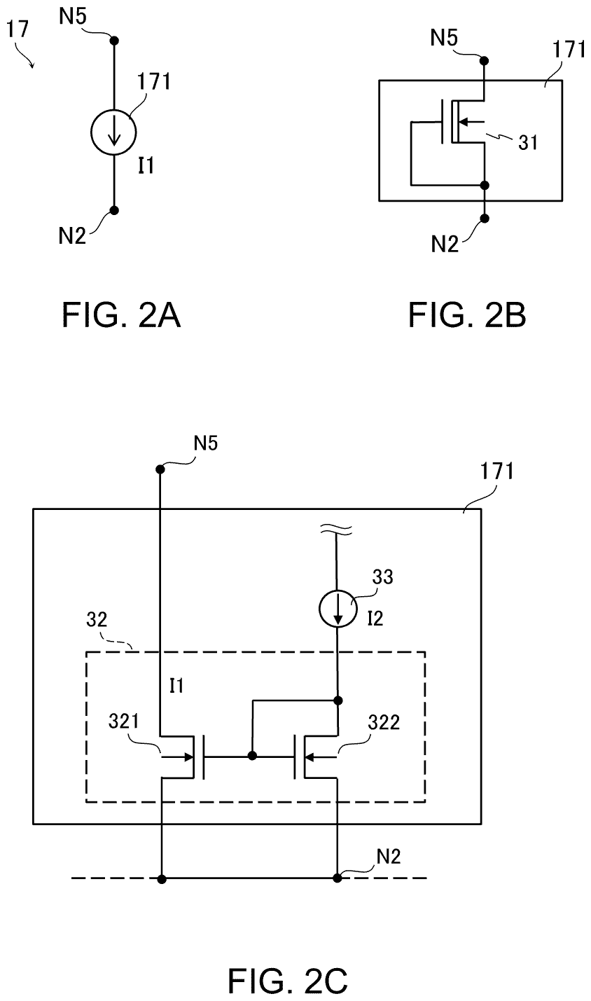

FIG. 1 is a circuit diagram of a semiconductor device 10A including a protection circuit 20A, which is an example of a semiconductor device including a protection circuit according to a first embodiment. FIG. 2A is a circuit diagram illustrating a current source 171 serving as a first configuration example of a load 17, and FIG. 2B and FIG. 2C are circuit diagrams illustrating a first configuration example and a second configuration example of the current source 171, respectively.

Referring to FIG. 1, a protection circuit 20A and a semiconductor device 10A are described. The semiconductor device 10A includes an analog circuit 11, a digital circuit 12, a protection circuit 20A, and a voltage drop circuit 15. The analog circuit 11, the digital circuit 12, the protection circuit 20A, and the voltage drop circuit 15 form a semiconductor integrated circuit formed on a semiconductor substrate.

Here, the digital circuit 12, as a first circuit, generally exhibits larger current fluctuations and maximum values during operation than the analog circuit 11, as the digital circuit 12 handles a switching power source with a large current together with a switching operation, a charge pump, and or a discrete signal. Thus, in the description of the embodiment, the digital circuit 12 is configured to include a noise source.

The analog circuit 11, as a second circuit, is a circuit that may be affected by noise. In the case where no noise countermeasures are implemented, the analog circuit 11 may be affected by the noise generated from the noise source. However, in the semiconductor device 10A configured to be able to suppress the effects of noise generated from the noise source as described later, the analog circuit 11 is able to operate stably. The analog circuit 11 and the digital circuit 12 are protection objects that the protection circuit 20A protects from application of a power voltage with reverse polarity relative to the steady state, i.e., the analog circuit 11 and the digital circuit 12 are the protected circuit of the protection circuit 20A.

The analog circuit 11, the digital circuit 12, and the voltage drop circuit 15 each have a first port connected to a VDD terminal 1 and a second port connected to a GND terminal 2 if not connected through the protection circuit 20A. Here, each of the VDD terminal 1 and the GND terminal 2 is an example for a power terminal supplying a power voltage, the VDD terminal 1 supplying a voltage VDD as an example for the power voltage, the GND terminal 2 supplying a voltage GND as another example of the power voltage. The second ports of the analog circuit 11, the digital circuit 12, and the voltage drop circuit 15 are respectively connected to the protection circuit 20A, and are connected to the GND terminal 2 via the protection circuit 20A. Here, the connection point between the respective first ports of the analog circuit 11, the digital circuit 12, and the voltage drop circuit 15, and the VDD terminal 1 is referred to as a node N1.

The voltage drop circuit 15 as a gate voltage control circuit includes, for example, a depletion-type NMOS transistor 16, a load 17, and an output port 15o connected to the connection point between the depletion-type NMOS transistor 16 and the load 17. The second port of the load 17, which is another port with respect to the first port connected to the depletion-type NMOS transistor 16 and the output port 15o, is connected to the second port of the analog circuit 11. Here, the connection point between the load 17 and the analog circuit 11 is referred to as a node N2. The voltage drop circuit 15 having the depletion-type NMOS transistor 16 further includes an input port 15i connected to the gate of the depletion-type NMOS transistor 16, forming a so-called source follower.

Here, referring to FIGS. 2A to 2C, a configuration example of the load 17 will be described. The load 17 is, for example, a current source 171 that supplies a constant current I1 in a direction from a node N5 to the node N2, as illustrated in FIG. 2A. The current source 171 is configured, for example, to have a depletion-type NMOS transistor 31 in which the gate and the source are connected (see FIG. 2B), or has a current source 33 that supplies a constant current I2 to the drain of the NMOS transistor 322 and a current mirror circuit 32 (see FIG. 2C).

The current mirror circuit 32 is configured, for example, to have an NMOS transistor 321 and an NMOS transistor 322 including a gate is connected to the gate of the NMOS transistor 321 and the drain of the NMOS transistor 321 itself. The current mirror circuit 32 flows a constant current I1 (=mI2) to the drain of the NMOS transistor 321, copying the constant current I2 at a predetermined mirror ratio m (where m is any positive number).

Referring to FIG. 1 again, the protection circuit 20A is described. The protection circuit 20A includes an NMOS transistor 21 connected between the analog circuit 11 and the GND terminal 2, and an NMOS transistor 22 connected between the digital circuit 12 and the GND terminal 2.

The NMOS transistor 21 as a second protection transistor includes, for example, a drain and a gate, as well as a source and a back gate connected to the node N2. The node N2 is a node serving as the reference with respect to the analog circuit 11.

The NMOS transistor 22 as a first protection transistor includes, for example, a drain connected to the drain of the NMOS transistor 21, a gate connected to the gate of the NMOS transistor 21, and a source and a back gate connected to a node N3. The node N3 is a node serving as the reference with respect to the digital circuit 12.

The drain of the NMOS transistor 21 and the drain of the NMOS transistor 22 are connected. Here, the connection point between the drain of the NMOS transistor 21 and the drain of the NMOS transistor 22 is referred to as a node N4. The node N4 is connected to the GND terminal 2. The node N5, which is the connection point between the gate of the NMOS transistor 21 and the gate of the NMOS transistor 22, is connected to the output port 15o of the voltage drop circuit 15.

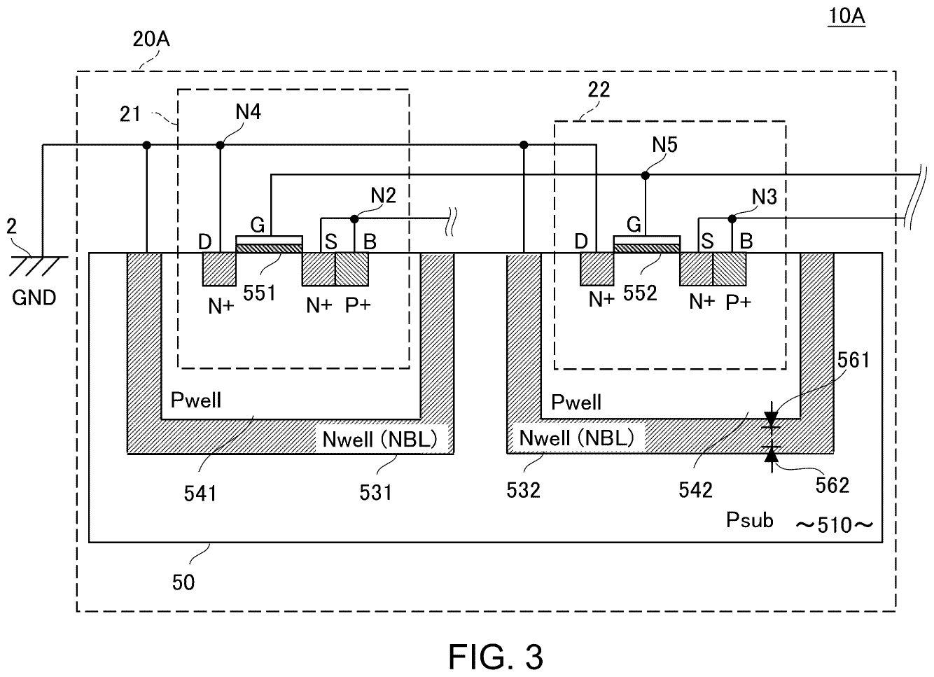

FIG. 3 is a cross-sectional view of the protection circuit 20A. The protection circuit 20A is formed on a semiconductor substrate 50 as a semiconductor integrated circuit. At least a portion of the semiconductor substrate 50 has a so-called triple well structure. For example, the semiconductor substrate 50 in the semiconductor device 10A has a triple well structure. The triple well structure includes a substrate region 510 of P-type as a first conductivity type, partition regions 531, 532 (labeled as “Nwell(NBL)” in the figure) as well regions of N-type as a second conductivity type, and well regions 541 and 542 of P-type as the first conductivity type.

The partition regions 531 and 532 are formed in the substrate region 510. The well region 541 is formed in an inner part and surrounded by the partition region 531. The well region 542 is formed in an inner part and surrounded by the partition region 532. The NMOS transistors 21 and 22 are formed on the well regions 541 and 542, respectively. A gate G of the NMOS transistor 21 is provided via the well region 541 and the insulation layer 551. A gate G of the NMOS transistor 22 is provided via the well region 542 and the insulation layer 552.

Here, the partition regions 531, 532 and drains D and sources S of the NMOS transistors 21, 22 are formed with a higher impurity concentration (N+) than an N-type semiconductor region not illustrated in the figure among N-type semiconductor regions. Back gates B of the NMOS transistors 21, 22 are formed with a higher impurity concentration (P+) than the substrate region 510 and the well regions 541, 542.

The drain D of the NMOS transistor 21 is connected to the partition region 531. The drain D of the NMOS transistor 22 is connected to the partition region 532. The connection point between the drain D of the NMOS transistor 21 and the partition region 531 is connected to the connection point between the drain D of the NMOS transistor 22 and the partition region 532, and forms the node N4.

Then, the operation of the protection circuit 20A and the semiconductor device 10A will be described. In the description of the operation of the protection circuit 20A and the semiconductor device 10A, it is assumed that the analog circuit 11 and the digital circuit 12 are circuits that allow a reverse current via a parasitic diode to flow in a state where the protection circuit 20A is not connected and a negative voltage is applied to the VDD terminal 1, i.e., a state where a power voltage with reverse polarity relative to the steady state is applied.

First, in the case where a positive voltage is applied to the VDD terminal 1, i.e., in the steady state, the current flowing through the inner part of the analog circuit 11 flows in a direction from the node N1 to the node N2, and the current flowing through the inner part of the digital circuit 12 flows in a direction from the node N1 to the node N3. The voltage drop circuit 15 supplies a gate voltage Vg of the NMOS transistor 22 as a first control voltage and a gate voltage Vg of the NMOS transistor 21 as a second control voltage to the gates of the NMOS transistor 21, 22, respectively.

In the case of controlling the NMOS transistor 21 and the NMOS transistor 22 by using the voltage drop circuit 15 using the source follower as exemplified in FIG. 1, it suffices to appropriately set a bias voltage Vbias, which is the gate voltage of the depletion-type NMOS transistor 16 as the voltage drop transistor, i.e., a voltage received by the input port 15i, so that the voltage of the node N5 that is each gate voltage Vg becomes higher than a threshold voltage Vth1 of the NMOS transistor 21 and a threshold voltage Vth2 of the NMOS transistor 22.

In the case where the NMOS transistor 21 and the NMOS transistor 22 are turned on and cause currents to flow from the respective sources (the node N2 and the node N3) to the drains (the node N4), by using the bias voltage Vbias, the gate-source voltage Vgs of the depletion-type NMOS transistor 16, and the threshold voltage Vth_sf of the depletion-type NMOS transistor 16, the bias voltage Vbias is set so that the gate voltage Vg satisfies Equation (1) and (2) in the following:

$$Vg = Vbias - Vgs {}_{}^{\cdot } {=}_{\cdot }^{} Vbias - Vth\_sf > Vth 1 \qquad ( 1 )$$

$$Vg = Vbias - Vgs {}_{}^{\cdot } {=}_{\cdot }^{} Vbias - Vth\_sf > Vth 2 \qquad ( 2 )$$

In the case of applying the depletion-type transistor to the voltage drop transistor, since the threshold voltage Vth_sf becomes negative, it is possible to make the gate voltage Vg equal to or greater than the bias voltage Vbias (Vg≥Vbias). In other words, by applying the depletion-type transistor such as the depletion-type NMOS transistor 16 as the voltage drop transistor, it becomes easier to turn on the NMOS transistor 21 and the NMOS transistor 22.

In addition, for stable operation of the analog circuit 11 and the digital circuit 12, it is desirable to operate the node N2 and the node N3 at a voltage close to the voltage GND. In such case, the NMOS transistor 21 and the NMOS transistor 22 as protection transistors operate in a resistance region where the drain-source voltage is close to 0V. Thus, the current flowing from the VDD terminal 1 to the node N2 flows to the GND terminal 2 via the ON-resistance of the NMOS transistor 21. The current flowing from the VDD terminal 1 to the node N3 flows to the GND terminal 2 via the ON-resistance of the NMOS transistor 22.

Here, in the case where the NMOS transistor 21 and the NMOS transistor 22 operate in the resistance region where the drain-source voltage close to 0V, the voltage Vint_gnd1_ope of the node N2 can be expressed by Equation (3) using by setting Ron21 as the resistance value of the ON-resistance of the NMOS transistor 21 and Iope_gnd1 as the current value a current flowing from the node N2 to the node N4. In addition, the voltage Vint_gnd2_ope of the node N3 can be expressed by Equation (4) setting the resistance value of the ON-resistance of the NMOS transistor 22 as Ron22 and the current value the current flowing from the node N3 to the node N4 as Iope_gnd2.

$$Vint\_gnd1 \_ope = Ron 21 \times Iope\_gnd1 \qquad ( 3 )$$

$$Vint\_gnd2 \_ope = Ron 22 \times Iope\_gnd2 \qquad ( 4 )$$

In the case where the NMOS transistor 22 is separated from the NMOS transistor 21 by being formed in the well region 542 within the partition region 532, as exemplified by the protection circuit 20A in FIG. 1 and FIG. 3, the current from the digital circuit 12 flows into the NMOS transistor 22 via the node N3. The fluctuation of the current from the digital circuit 12 is converted into the voltage fluctuation of the source S by using the ON-resistance (resistance value Ron22) of the NMOS transistor 22.

At this time, the voltage of the well region 542, which is the back gate B of the NMOS transistor 22, also fluctuates. Here, in the case where the direction from the well region 542 to the substrate region 510 as the forward direction, the voltage fluctuation of the well region 542 propagates to the partition region 532 via the parasitic diode 561 that is forward-biased between the well region 542 and the partition region 532. However, the parasitic diode 562 between the partition region 532 and the substrate region 510, which forms a bonding interface, is reverse-biased. Thus, the propagation of the voltage fluctuation of the well region 542, i.e., noise, to the substrate region 510 is blocked.

Then, in the state in which a negative voltage is applied to the VDD terminal 1, i.e., in the case where a power voltage with reverse polarity relative to the steady state is applied, in the analog circuit 11, a reverse current flows from the node N2 to the node N1 via the parasitic diode. In the digital circuit 12, a reverse current flows from the node N3 to the node N1 via the parasitic diode. At this time, the gate voltage Vg of the NMOS transistors 21 and 22, and the voltage Vint_gnd1_ope of the node N2 and the voltage Vint_gnd2_ope of the node N3 decrease following the voltage of the VDD terminal 1. As a result, the gate-source voltage of the NMOS transistor 21 falls below the threshold voltage Vth1 and is turned off. The gate-source voltage of the NMOS transistor 22 falls below the threshold voltage Vth2 and is turned off.

Considering the cross-sectional structure, in the state where a negative voltage is applied to the VDD terminal 1, the voltages of the well regions 541, 542 and the substrate region 510 become lower than or equal to the voltage GND of the GND terminal 2, and lower than the voltages of the partition regions 531, 532. Thus, the parasitic diode (not shown) between the well region 541 and the partition region 531, the parasitic diode (not shown) between the partition region 531 and the substrate region 510, the parasitic diode 561 between the well region 542 and the partition region 532, and the parasitic diode 562 between the partition region 532 and the substrate region 510 are all in a reverse-biased state. In other words, in the state where a negative voltage is applied to the VDD terminal 1, all the parasitic diodes formed within the triple well structure including the well regions 541, 542, the partition regions 531, 532, and the substrate region 510 are reverse-biased, so the reverse current is blocked.

As described above, according to the protection circuit 20A and the semiconductor device 10A, since the protection circuit 20A has the NMOS transistors 21 and 22, it is possible to protect the analog circuit 11 and the digital circuit 12 from the application of a power voltage with reverse polarity.

More specifically, by satisfying at least one of forming the NMOS transistor 21 in the well region 541 in the partition region 531, and forming the NMOS transistor 22 in the well region 542 in the partition region 532, the node N2 and the node N3 are physically and electrically separated by the partition regions 531, 532. Thus, the semiconductor device 10A can suppress the undesirable effects of noise from the noise source while suppressing cost increases. In other words, according to the protection circuit 20A and the semiconductor device 10A, it is possible to block the propagation of voltage fluctuations indicated by Equation (4) above from the digital circuit 12 to another circuit such as the analog circuit 11.

In the state where a negative voltage is applied to the VDD terminal 1, all the parasitic diodes formed within the triple well structure including the well regions 541, 542, the partition regions 531, 532, and the substrate region 510 are reverse-biased, so it is possible to block the reverse current.

According to the protection circuit 20A and the semiconductor device 10A, as can be understood from Equations (3) and (4), by adjusting the resistance values of the ON-resistances of the NMOS transistors 21 and 22 to appropriate values, it is possible to individually adjust the voltage drop from the node N2 to the node N4 and the voltage drop from the node N3 to the node N4. In other words, according to the protection circuit 20A and the semiconductor device 10A, it is possible to increase the degree of freedom in the circuit design for the protection circuit 20A and the semiconductor device 10A. The adjustment of the resistance values of the ON-resistances of the NMOS transistors 21 and 22 can be appropriately selected from several methods, such as changing the aspect ratios of the NMOS transistors 21 and 22.

### Second Embodiment

A protection circuit and a semiconductor device including the protection circuit according to the second embodiment of the present invention differ from the protection circuit and the semiconductor device including the protection circuit according to the first embodiment in that the drain of the formed protection transistor is connected to the substrate region, and the partition region is not connected to any port and is therefore an independent node, i.e., it is floating. However, the embodiments do not substantially differ in other aspects. In other words, the protection circuit and the semiconductor device including the protection circuit according to the second embodiment do not substantially differ in circuit configuration from the protection circuit and the semiconductor device including the protection circuit according to the first embodiment, but differ in the connection relationship between the protection transistor and the semiconductor substrate. Thus, in the embodiment, the description will focus on the differences, and redundant explanation for aspects that do not substantially differ will be omitted.

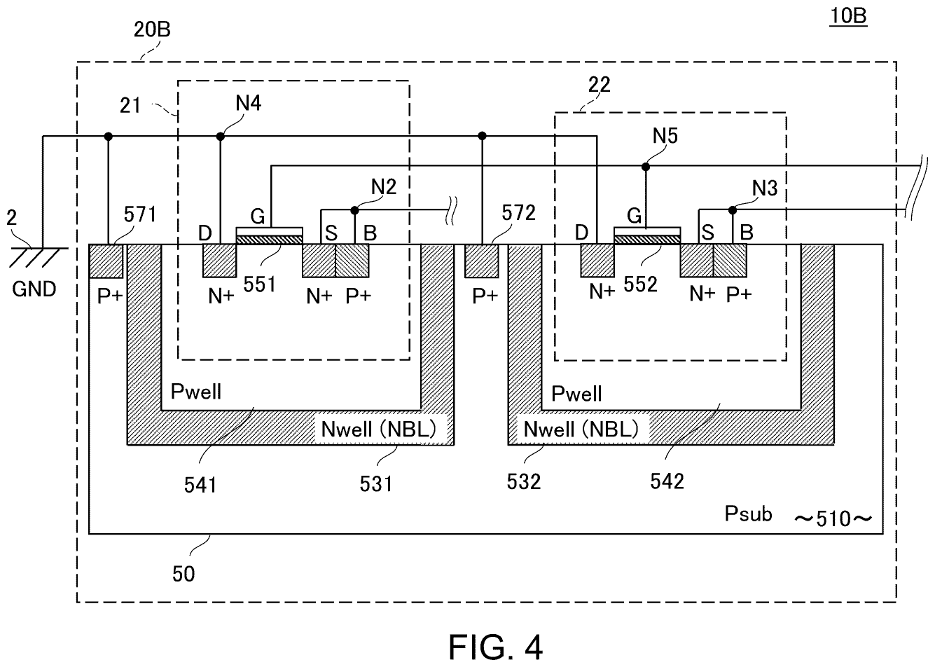

FIG. 4 is a cross-sectional view of a semiconductor device 10B including a protection circuit 20B, which is an example of a semiconductor device including a protection circuit according to a second embodiment.

The semiconductor device 10B differs from the semiconductor device 10A in that the semiconductor device 10B includes the protection circuit 20B instead of the protection circuit 20A, but does not substantially differ in other aspects. Additionally, the protection circuit 20B differs from the protection circuit 20A in the connection destination of the drain D of the NMOS transistor 21 formed in the well region 541, the connection destination of the drain D of the NMOS transistor 22 formed in the well region 542, and |that the partition regions 531 and 532 are floating, but does not substantially differ in other aspects.

In the protection circuit 20B, the drain D of the NMOS transistor 21 is connected to the connection port 571 electrically connected to the substrate region 510. The drain D of the NMOS transistor 22 is connected to the connection port 572 electrically connected to the substrate region 510. The connection ports 571 and 572 are regions formed in a region with a higher impurity concentration (P+) than the substrate region 510 and the well regions 541 and 542 in the substrate region 510. Meanwhile, the partition regions 531 and 532 are not connected to any port, and are therefore floating.

Then, the operation of the protection circuit 20B and the semiconductor device 10A will be described. In describing the operation of the protection circuit 20B and the semiconductor device 10B, it is assumed that there is no circuit that uses the voltage of the substrate region 510 as a reference, and the content that does not substantially differ from the operation of the protection circuit 20A and the semiconductor device 10A will be omitted.

Assuming that there is no circuit within the semiconductor device 10B that uses the voltage of the substrate region 510 as a reference, in the protection circuit 20B and the semiconductor device 10B, the well regions 541 and 542 are connected to the GND terminal 2 via the NMOS transistors 21 and 22. Additionally, the substrate region 510 (more specifically, the connection ports 571 and 572) is connected to the GND terminal 2, and the partition regions 531 and 532 are floating.

The protection circuit 20B and the semiconductor device 10B so connected can, in the steady state, secure a current path by turning on the NMOS transistors 21 and 22, similar to the protection circuit 20A and the semiconductor device 10A. On the other hand, in the case where a power voltage with reverse polarity relative to the steady state is applied, the parasitic diodes (not shown) between the well regions 541, 542 and the partition regions 531, 532, or the parasitic diodes (not shown) between the partition regions 531, 532 and the substrate region 510 become reverse biased. As a result, similar to the protection circuit 20A and the semiconductor device 10A, the reverse current is blocked by the reverse-biased parasitic diodes.

As described above, the protection circuit 20B and the semiconductor device 10B can achieve effects similar to those of the protection circuit 20A and the semiconductor device 10A. In other words, the analog circuit 11 and the digital circuit 12 can be protected from application of the power voltage with reverse polarity. The freedom in circuit design for the protection circuit 20B and the semiconductor device 10B can be increased.

According to the protection circuit 20B and the semiconductor device 10B, since the substrate region 510 and the GND terminal 2 are connected, the substrate region 510 can be used stably. In addition, at the time of encapsulating an integrated circuit (IC) including the protection circuit 20B into a package with a solder surface on the back side, the workability of electrical connection testing between the package and the IC, or between the package and the mounting substrate can be improved.

The present invention is not limited to the embodiments described above, and at the implementation stage, it can be implemented in various forms other than the examples described above. Within the scope without departing from the gist of the present invention, various omissions, additions, substitutions, or modifications can be made.

In the protection circuit and the semiconductor device including the protection circuit are according to the embodiment, for example, in the protection circuit 20A and the semiconductor device 10A, the partition region 531 and the partition region 532 are respectively connected to the drain of the NMOS transistor 21 and the drain of the NMOS transistor 22, respectively, i.e., to the node N4. However, the present invention is not limited thereto. It may also be configured that one of the partition region 531 and the partition region 532 in the protection circuit 20A and the semiconductor device 10A is floating, while the other of the partition region 531 and the partition region 532 is connected to the node N4.

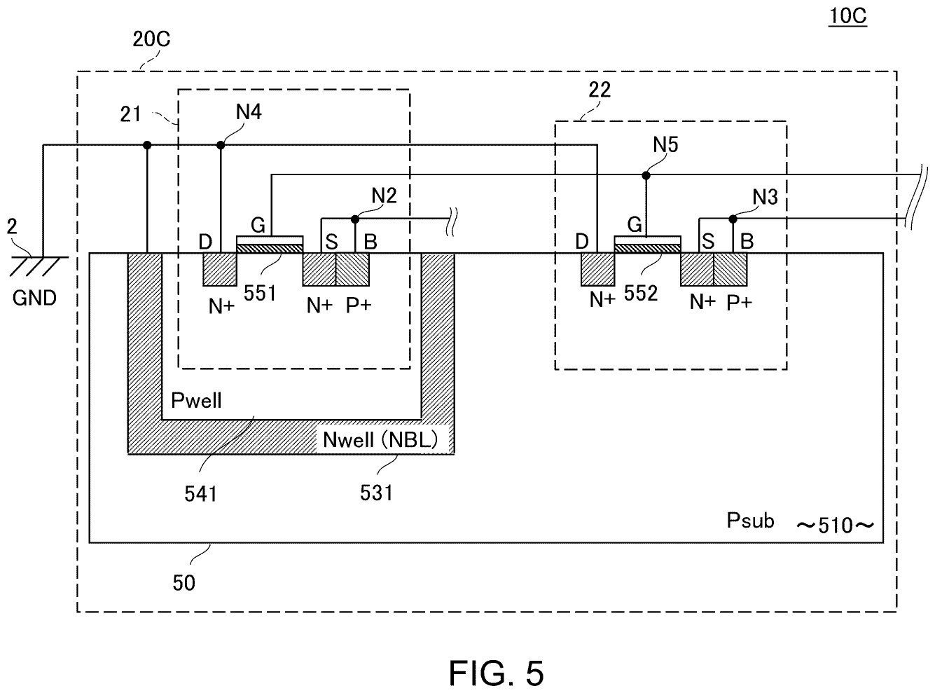

In the protection circuit 20B and the semiconductor device 10B, it is not necessary for both of the connection ports 571 and 572 to be formed. It suffices as long as at least one of the connection ports 571 and 572 is formed. In other words, it suffices as long as one of the connection ports 571 and 572 is connected to the GND terminal 2, and the other of the connection ports 571 and 572 may be omitted. Also, as illustrated in FIGS. 5 to 11 described later, the embodiments may be modified.

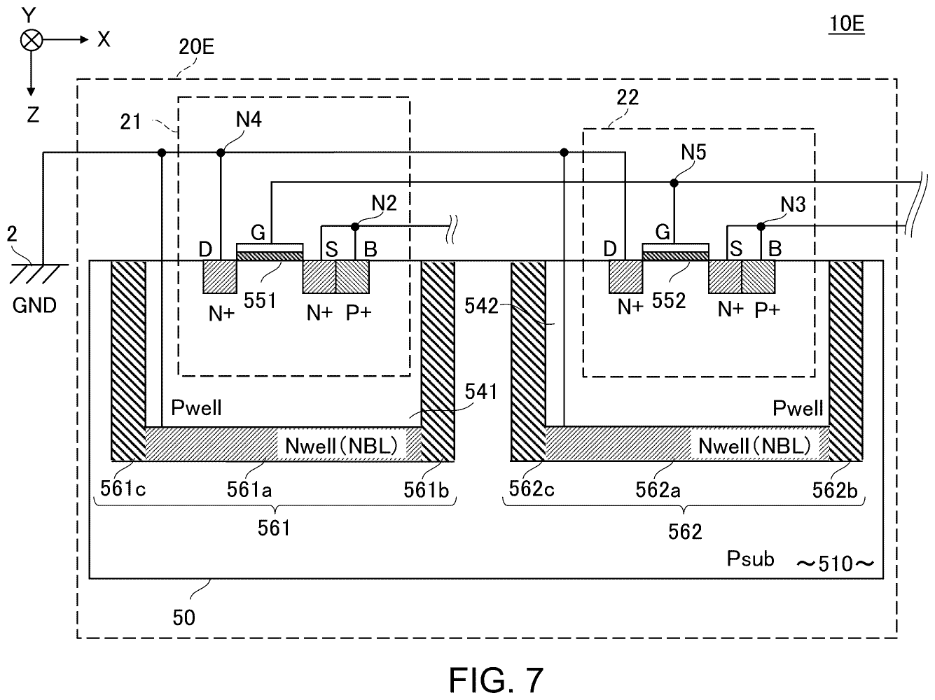

FIGS. 5, 6, and 7 are cross-sectional views respectively illustrating a semiconductor device 10C of a first modified example, a semiconductor device 10D of a second modified example, and a semiconductor device 10E of a third modified example of the first embodiment. X-axis, Y-axis, and Z-axis illustrated in FIG. 7 are the three axes in a three-dimensional orthogonal coordinate system. In the embodiment, X-axis direction, Y-axis direction, and Z-axis direction correspond to the horizontal direction, the vertical direction, and the depth direction, respectively.

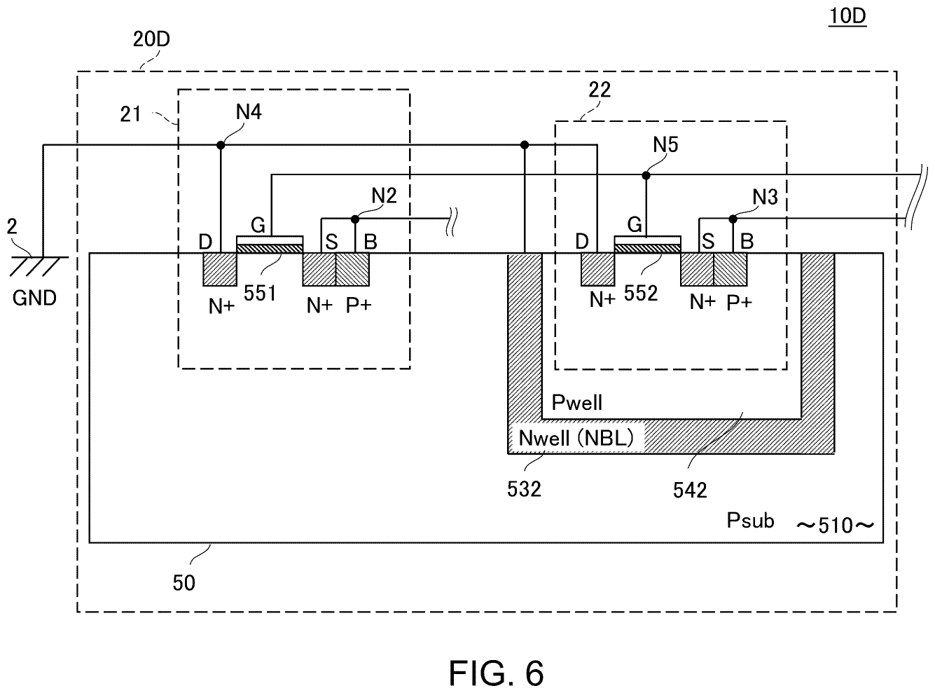

The protection circuit and the semiconductor device according to the embodiment may be, for example, a protection circuit 20C and a semiconductor device 10C in which the partition region 532 and well region 542 are omitted (see FIG. 5) from the protection circuit 20A and the semiconductor device 10A, or a protection circuit 20D and a semiconductor device 10D in which the partition region 531 and the well region 541 are omitted (see FIG. 6). Since the protection circuit 20C and the semiconductor device 10C and the protection circuit 20D and the semiconductor device 10D function similarly to the protection circuit 20A and the semiconductor device 10A, similar effects to the effects of the protection circuit 20A and the semiconductor device 10A can be obtained.

In the protection circuit and the semiconductor device according to the embodiment, the partition region 532 and the well region 542 may be omitted, or the partition region 531 and the well region 541 may be omitted, from the protection circuit 20B and the semiconductor device 10B. For the protection circuit and the semiconductor device in which the partition region 532 and the well region 542 are omitted, or the protection circuit and the semiconductor device in which the partition region 531 and well region 541 are omitted, from the protection circuit 20B and the semiconductor device 10B, similar effects to the effects of the protection circuit 20B and the semiconductor device 10B can be obtained.

With respect to the protection circuit 20A and the semiconductor device 10A, or with respect to the protection circuit 20B and the semiconductor device 10B, the protection circuit and the semiconductor device according to the embodiment may be configured to include partition regions 561, 562 in place of the partition regions 531, 532. The partition regions 561, 562 are the same as the partition regions 531, 532 in having Nwell 561a, 562a, respectively, but differ in further having a region in which a portion is formed by an insulation material.

A portion of the partition region 561 includes, for example, a region formed by an N-type semiconductor, such as an Nwell 561a formed with a predetermined width in a direction along the depth direction, that is, at approximately the same depth. The two ends of the Nwell 561a are respectively bonded to trenches 561b and 561c that are insulators. The trenches 561b and 561c contain an air region (hollow region) as an example of the insulator, that is, the trenches 561b and 561c are simply formed as a groove, but may contain an oxide such as SiO₂ as another example of the insulator. The partition region 562 is configured similarly to the partition region 561.

The partition regions 561, 562 illustrated in FIG. 7 are examples where the Nwell 561a is uniformly formed at approximately the same depth, but the position or the size of the Nwell 561a are not limited to the location as illustrated. In the partition regions 561, 562, the Nwell 561a, 562a may be included in at least a portion of any of the following portions: among the region extending along the depth direction, a first portion which is a region on the side where X is smaller, a second portion which is a region on the side where X is larger, and a third portion which is a region extending along the horizontal direction. That is, any of the first region, the second region, and the third region may be formed to include the Nwell 561a and an insulator. Additionally, in the partition regions 561, 562, for example, one of the first region and the second region may be formed with the Nwells 561a, 562a, while the other of the first region and the second region, and the third region may be formed with the insulator. The Nwells 561a, 562a, illustrated in FIG. 7, serving as the N-type semiconductor region included in the partition regions 561, 562 are floating, but may connect to the node N4.

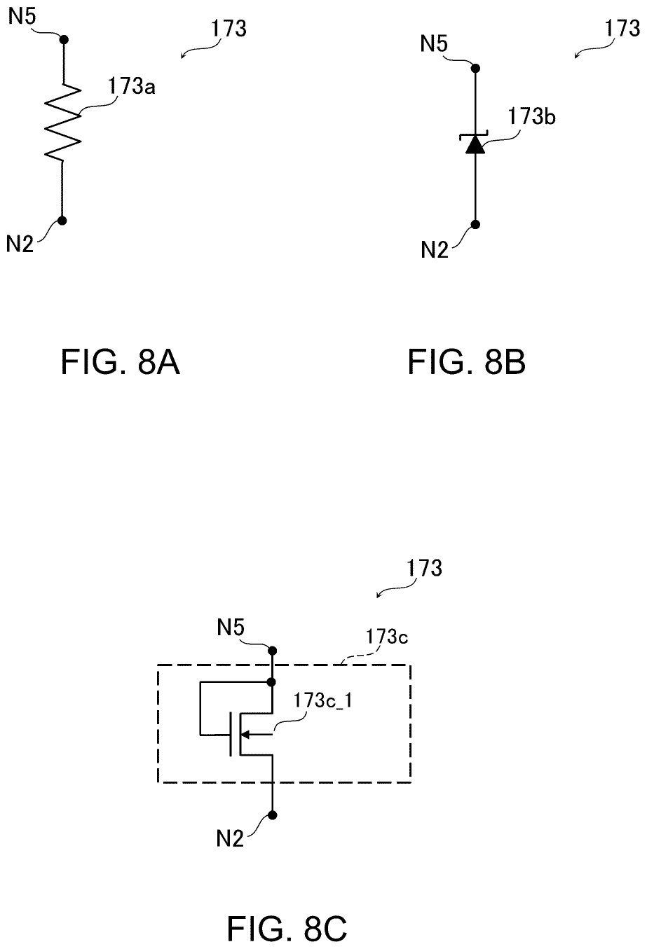

Additionally, while the voltage drop circuit 15 is an example having the current source 171 as an example of the load 17, it may also be configured to have an I/V conversion circuit 173 (see FIGS. 8A to 8C) that converts current to voltage, in place of the current source 171.

FIGS. 8A to 8C are circuit diagrams illustrating second to fourth configuration examples of the load 17, respectively.

In the embodiment, as an example of the I/V conversion circuit 173, for the load 17, a resistance element 173a may be applied (second configuration example: see FIG. 8A), a Zener diode 173b may be applied (third configuration example: see FIG. 8B), or a transistor circuit 173c including at least one diode-connected MOS transistor 173c_1 may be applied (fourth configuration example: see FIG. 8C). The transistor circuit 173c is not limited to the case including one diode-connected MOS transistor 173c_1, but may also be configured with multiple diode-connected MOS transistors including the MOS transistor 173c_1 connected in series.

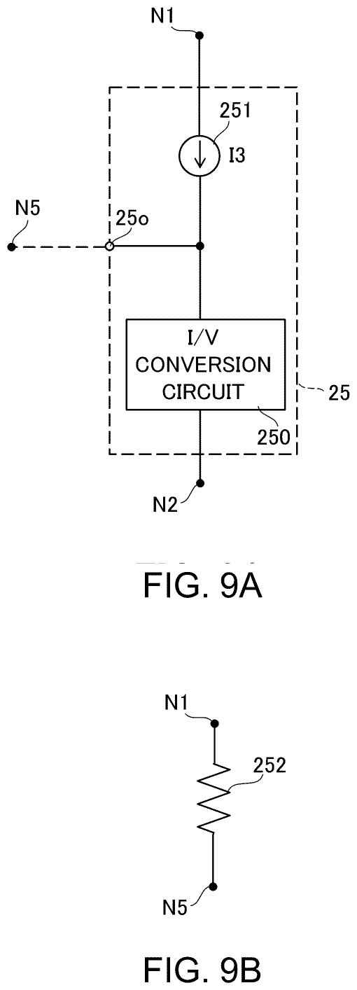

The semiconductor devices 10A to 10E include the voltage drop circuit 15, but may also include a voltage drop circuit 25 (see FIGS. 9A and 9B) in place of the voltage drop circuit 15.

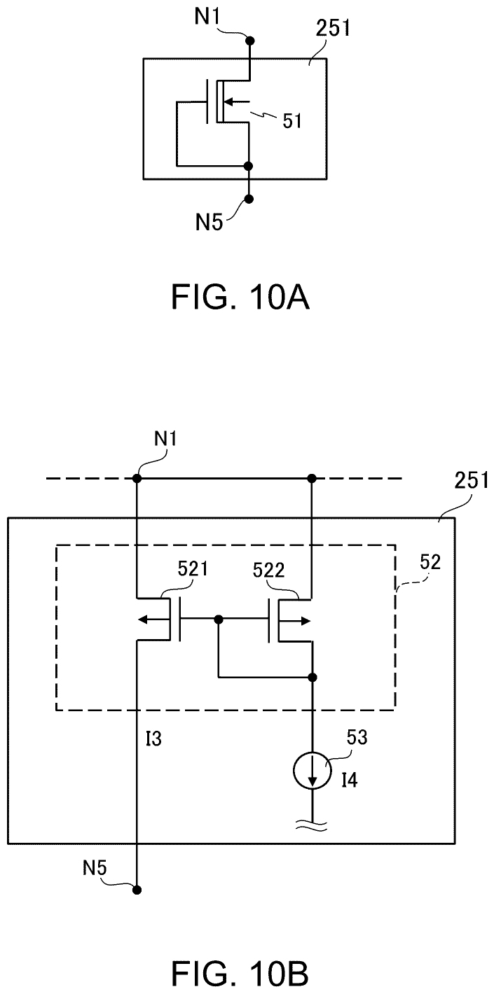

FIG. 9A is a circuit diagram of the voltage drop circuit 25 having a current source 251, and FIG. 9B is a partial circuit diagram of the voltage drop circuit 25 having a resistance element 252 in place of the current source 251. Additionally, FIG. 10A is a circuit diagram illustrating a first configuration example of the current source 251, and FIG. 10B is a circuit diagram illustrating a second configuration example of the current source 251.

In the embodiment, as exemplified in FIG. 9A, the voltage drop circuit 25 has the current source 251 in place of the depletion-type NMOS transistor 16 in the voltage drop circuit 15, has an I/V conversion circuit 250 in place of the load 17, and further has an output port 25o corresponding to the output port 15o. The voltage drop circuit 25 may include a resistance element 252 in place of the current source 251, as illustrated in part in FIG. 9B.

The current source 251 is configured, for example, to have a depletion-type NMOS transistor 51 in which the gate and the source are connected (see FIG. 10A), or have a current source 53 that supplies a constant current I4 to the drain of the PMOS transistor 522 and a current mirror circuit 52 (see FIG. 10B).

The current mirror circuit 52 is configured, for example, with a PMOS transistor 521 including a gate connected to the drain of its own, and a PMOS transistor 522 including a gate connected to the gate and the drain of the PMOS transistor 521. The current mirror circuit 52 flows a constant current I3 (=kI4) to the drain of the PMOS transistor 521, copying the constant current I4 at a predetermined mirror ratio k (where k is any positive number).

Similar to the I/V conversion circuit 173, in the I/V conversion circuit 250, a resistance element, a Zener diode, a single diode-connected MOS transistor, or a transistor circuit configured by connecting multiple diode-connected MOS transistors in series may be applied.

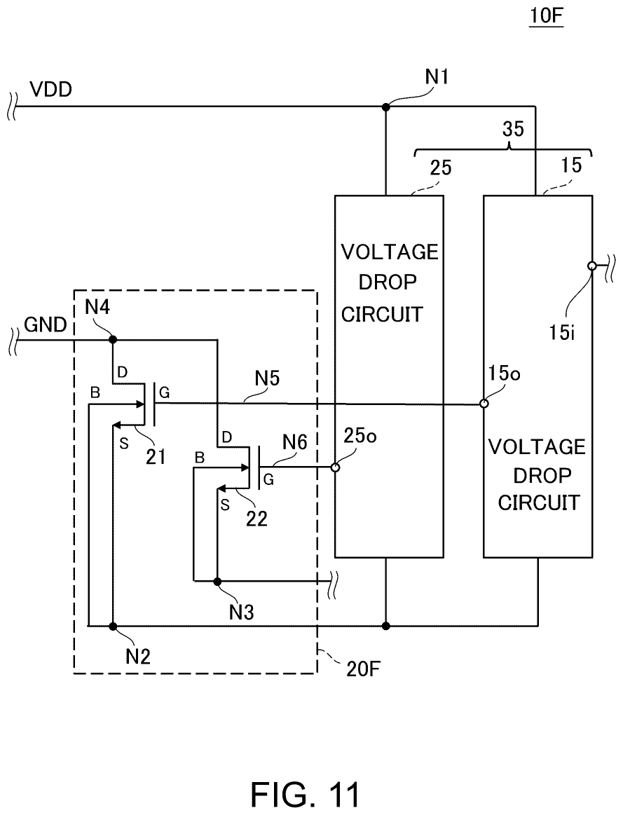

The protection circuits 20A to 20E are examples without the voltage drop circuit 15 or the voltage drop circuit 25, but the protection circuits 20A to 20E are not limited to the examples. The protection circuits 20A to 20E and a protection circuit 20F (see FIG. 11) to be described later may be configured to further include the voltage drop circuit 15, 25 or a voltage drop circuit 35 (see FIG. 11) to be described later.

In the protection circuits 20A to 20E, the NMOS transistor 21 and the NMOS transistor 22 are examples including a common gate, but the gate of the NMOS transistor 21 and the gate of the NMOS transistor 22 do not need to be common. That is, the gate of the NMOS transistor 21 and the gate of the NMOS transistor 22 may be independent. In the case where the gates of the NMOS transistor 21 and the NMOS transistor 22 are independent, a voltage drop circuit may be formed by combining the voltage drop circuit 15 and the voltage drop circuit 25 to be able to supply independent gate voltages.

FIG. 11 is a partial circuit diagram of a protection circuit 20F and a semiconductor device 10F, which are an example of the protection circuit and the semiconductor device including the protection circuit according to the embodiment. In FIG. 11, for clarity and conciseness, the analog circuit 11 and the digital circuit 12 connected similarly to FIG. 1 are omitted from the illustration.

The semiconductor device 10F differs from the semiconductor device 10A in that the semiconductor device 10F includes the protection circuit 20F in place of the protection circuit 20A, and includes the voltage drop circuit 35 in place of the voltage drop circuit 15, but does not substantially differ in other aspects. The protection circuit 20F differs from the protection circuit 20A in that the gate of the NMOS transistor 21 and the gate of the NMOS transistor 22 form different (independent) nodes N5 and N6, respectively, but do not substantially differ in other aspects. The voltage drop circuit 35 as a gate voltage control circuit is a voltage drop circuit capable of outputting two independent voltages, and, as illustrated in FIG. 11, includes one voltage drop circuit 15 and one voltage drop circuit 25.

The voltage drop circuit 35 illustrated in FIG. 11 is an example where the voltage drop circuit 25 supplying voltage to the gate of the NMOS transistor 22 is connected between the node N1 and the node N2. However, the present invention is not limited thereto. The voltage drop circuit 25 that supplies voltage to the gate of the NMOS transistor 22 may be connected to the node N3 instead of the node N2. Additionally, the voltage drop circuit 35 illustrated in FIG. 11 is an example that includes one voltage drop circuit 15 and one voltage drop circuit 25, but it is not limited thereto. The voltage drop circuit 35 may also include two voltage drop circuits 15 or two voltage drop circuits 25.

The protection circuits 20A to 20F and the semiconductor devices 10A to 10F described above are examples where the first conductivity type and the second conductivity type are P-type and N-type, respectively, and VDD is a positive voltage in the steady state. However, the present invention is not limited to this configuration. The protection circuit and the semiconductor device according to the embodiment may also be arranged by interchanging the conductivity type of the semiconductor substrate 50 (P-type and N-type), the polarity of elements having polarity such as the NMOS transistors 21 and 22, and the polarity of the power voltage (positive and negative).

The embodiments and the modified examples thereof are included in the scope and the gist of the present invention, as well as within the scope of the present invention described in the claims and its equivalents.

What is claimed is:

1. A protection circuit formed on a semiconductor substrate and protecting a protected circuit from application of a power voltage with reverse polarity relative to a steady state, the semiconductor substrate having, in at least a portion, a triple well structure, the protected circuit including a noise source, a first circuit which is arranged between a first power terminal and a second power terminal and is connected to the second power terminal via the protection circuit, and a second circuit connected in parallel with the first circuit via the protection circuit between the first power terminal and the second power terminal, the triple well structure including a substrate region having a first conductivity type, a partition region formed in the substrate region and including, in at least a portion, a semiconductor region having a second conductivity type, and a well region having the first conductivity type and formed in an inner part surrounded by the partition region, the protection circuit comprising:
a first protection transistor including a drain connected to the second power terminal, a gate receiving supply of a first control voltage, and a source and a back gate which are connected to the first circuit, and
a second protection transistor including a drain connected to the drain of the first protection transistor, a gate receiving supply of a second control voltage, and a source and a back gate which are connected to the second circuit while not connected to a connection point between the source and the back gate of the first protection transistor and the first circuit,
at least one protection transistor of the first protection transistor and the second protection transistor being formed in the well region,
a drain of the at least one protection transistor being connected to one of the substrate region and the semiconductor region comprised in the partition region surrounding the well region.

2. The protection circuit as claimed in claim 1, wherein the drain of the protection transistor formed in the well region is connected to the substrate region and further connected to the second power terminal, and
the partition region surrounding the well region in which the protection transistor is formed floating.

3. The protection circuit as claimed in claim 1, wherein the drain of the protection transistor formed in the well region is connected to the partition region surrounding the well region, and is further connected to the second power terminal.

4. The protection circuit as claimed in claim 1, wherein the protection circuit includes a common node formed by being connected to a gate of the second protection circuit and a gate of the first protection transistor.

5. The protection circuit as claimed in claim 4, further comprising: a gate voltage control circuit which includes an output port to output a predetermined voltage as the first control voltage and the second control voltage, and is connected between the first power terminal and a connection point between the source and the back gate of the second protection transistor and the second circuit.

6. The protection circuit as claimed in claim 1, further comprising a gate voltage control circuit connected between the first power terminal and a connection point between the source and the back gate of the second protection transistor and the second circuit, and
the gate voltage control circuit has a first output port that outputs the first control voltage and a second output port that outputs the second control voltage.

7. The protection circuit as claimed in claim 1, further comprising a gate voltage control circuit that outputs the first control voltage and the second control voltage,
the gate voltage control circuit comprises: a first output port, provided between the first power terminal and a connection point between the source and the back gate of the first protection transistor and the first circuit, and outputting the first control voltage; and
a second output port, provided between the first power terminal and a connection point between the source and the back gate of the second protection transistor and the second circuit, and outputting the second control voltage.

8. A semiconductor device, comprising a semiconductor integrated circuit formed on a semiconductor substrate having, in at least a portion, a triple well structure, the protected circuit including a noise source, a first circuit which is arranged between a first power terminal and a second power terminal and is connected to the second power terminal via the protection circuit, and a second circuit connected in parallel with the first circuit via the protection circuit between the first power terminal and the second power terminal, the triple well structure including a substrate region having a first conductivity type, a partition region formed in the substrate region and including, in at least a portion, a semiconductor region having a second conductivity type, and a well region having the first conductivity type and formed in an inner part surrounded by the partition region, the semiconductor integrated circuit comprising: a protection circuit protecting a connected protected circuit from application of a power voltage with reverse polarity relative to a steady state, the protection circuit including a first protection transistor including a drain connected to the second power terminal, a gate receiving supply of a first control voltage, and a source and a back gate which are connected to the first circuit, and
a second protection transistor including a drain connected to the drain of the first protection transistor, a gate receiving supply of a second control voltage, and a source and a back gate which are connected to the second circuit while not connected to a connection point between the source and the back gate of the first protection transistor and the first circuit,
at least one protection transistor of the first protection transistor and the second protection transistor being formed in the well region,
a drain of the at least one protection transistor being connected to one of the substrate region and the partition region surrounding the well region.

9. The semiconductor device as claimed in claim 8, wherein the semiconductor integrated circuit further comprises a gate voltage control circuit connected between the first power terminal and a connection point between the source and the back gate of the second protection transistor and the second circuit, and
the gate voltage control circuit has an output port outputting at least one control voltage of the first control voltage and the second control voltage.

10. The semiconductor device as claimed in claim 8, wherein the semiconductor integrated circuit further comprises a gate voltage control circuit that outputs the first control voltage and the second control voltage,
the gate voltage control circuit comprises: a first output port, provided between the first power terminal and a connection point between the source and the back gate of the first protection transistor and the first circuit, and outputting the first control voltage; and
a second output port, provided between the first power terminal and a connection point between the source and the back gate of the second protection transistor and the second circuit, and outputting the second control voltage.

11. The semiconductor device as claimed in claim 8, wherein the semiconductor integrated circuit comprises the protected circuit.
